(19) United States
(12) Patent Application Publication
(10) Pub. No.: US 2026/0076160 A1
(43) Pub. Date: Mar. 12, 2026

(54) NITRIDE-BASED SEMICONDUCTOR DEVICE AND METHOD FOR MANUFACTURING THE SAME

(71) Applicant: INNOSCIENCE (ZHUHAI) TECHNOLOGY CO., LTD., Zhuhai, Guangdong (CN)

(72) Inventors: Jue OUYANG, Zhuhai, Guangdong (CN); Yong HAN, Zhuhai, Guangdong (CN); Lijie ZHANG, Zhuhai, Guangdong (CN); Xiao ZHANG, Zhuhai, Guangdong (CN); Wen-Yuan HSIEH, Zhuhai, Guangdong (CN)

(73) Assignee: INNOSCIENCE (ZHUHAI) TECHNOLOGY CO., LTD., Zhuhai, Guangdong (CN)

(21) Appl. No.: 19/105,943

(22) PCT Filed: Aug. 25, 2022
(86) PCT No.: PCT/CN2022/114809

§ 371 Date: Feb. 24, 2025

(51) Int. Cl. H01L 21/768; H01L 23/48; H01L 23/528; H10D 30/47; H10D 62/85

(52) U.S. Cl. CPC H10W 20/023; H10D 30/475; H10D 62/8503; H10W 20/20; H10W 20/435

(57) ABSTRACT

A method for manufacturing a nitride-based semiconductor device is provided. The method includes steps as follows. An epitaxy structure is formed on a silicon-based substrate. An oxide structure is formed on the epitaxy structure. A mask layer having an opening is formed on the epitaxy structure such that at least one portion is exposed from the opening in a chamber. A first halogen-based gas is introduced into the chamber to remove the exposed portion of the oxide structure such that a portion of the epitaxy structure is exposed. A second halogen-based gas different than the first halogen-based gas is introduced into the chamber to remove the exposed portion of the epitaxy structure such that a portion of the silicon-based substrate is exposed.

### CROSS-REFERENCE TO RELATED APPLICATIONS

This application is a national stage of international PCT application No. PCT/CN2022/114809 filed on Aug. 25, 2022, the entire contents of which are incorporated herein by reference.

### FIELD OF THE DISCLOSURE

The present disclosure generally relates to a nitride-based semiconductor device. More specifically, the present disclosure relates to a nitride-based semiconductor device having a TGV structure.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

### SUMMARY OF THE DISCLOSURE

In accordance with one aspect of the present disclosure, a method for manufacturing a nitride-based semiconductor device is provided. The method includes steps as follows. An epitaxy structure is formed on a silicon-based substrate. An oxide structure is formed on the epitaxy structure. A mask layer having an opening is formed on the epitaxy structure such that at least one portion is exposed from the opening in a chamber. A first halogen-based gas is introduced into the chamber to remove the exposed portion of the oxide structure such that a portion of the epitaxy structure is exposed. A second halogen-based gas different than the first halogen-based gas is introduced into the chamber to remove the exposed portion of the epitaxy structure such that a portion of the silicon-based substrate is exposed.

In accordance with one aspect of the present disclosure, a method for manufacturing a nitride-based semiconductor device is provided. The method includes steps as follows. An epitaxy structure is formed on a silicon-based substrate. An oxide structure is formed on the epitaxy structure. A mask layer having an opening is formed on the epitaxy structure such that at least one portion is exposed from the opening in a chamber. A first reactive-ion etching process is performed in the chamber by using a first halogen-based gas to remove the exposed portion of the oxide structure such that a portion of the epitaxy structure is exposed. A second reactive-ion etching process is performed in the chamber by using a second halogen-based gas different than the first halogen-based gas to remove the exposed portion of the epitaxy structure such that a portion of the silicon-based substrate is exposed.

In accordance with one aspect of the present disclosure, a nitride-based semiconductor device is provided. The nitride-based semiconductor device includes a silicon-based substrate, an epitaxy structure, an oxide structure, and a conductor filling. The epitaxy structure is disposed on the silicon-based substrate. The epitaxy structure has a first inner sidewall and a second inner sidewall at above the first inner sidewall and connected to the first inner sidewall, and the first inner sidewall and the second inner sidewall have different roughness and are oblique with respect to the silicon-based substrate. The oxide structure is disposed on the epitaxy structure. The oxide structure has an inner sidewall connected to the second inner sidewall and oblique with respect to the silicon-based substrate. The conductor filling extends from a position beneath the epitaxy structure to a position over the oxide structure.

By the above configuration, because the first etching process and the second etching process are performed as the structure is located in the same chamber, the performing the second etching process can follow the performing the first etching process without vacuum relief. For semiconductor devices, a structure at a transition stage may be damaged due to oxygen, so keeping free from vacuum relief can make process stability improved.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1 is a cross sectional view of a nitride-based semiconductor device according to some embodiments of the present disclosure;

FIG. 2A, FIG. 2B, and FIG. 2C show different stages of a method for manufacturing a nitride-based semiconductor device according to some embodiments of the present disclosure;

FIG. 3 is a cross sectional view of a nitride-based semiconductor device according to some embodiments of the present disclosure; and

FIG. 4 is a cross sectional view of a nitride-based semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

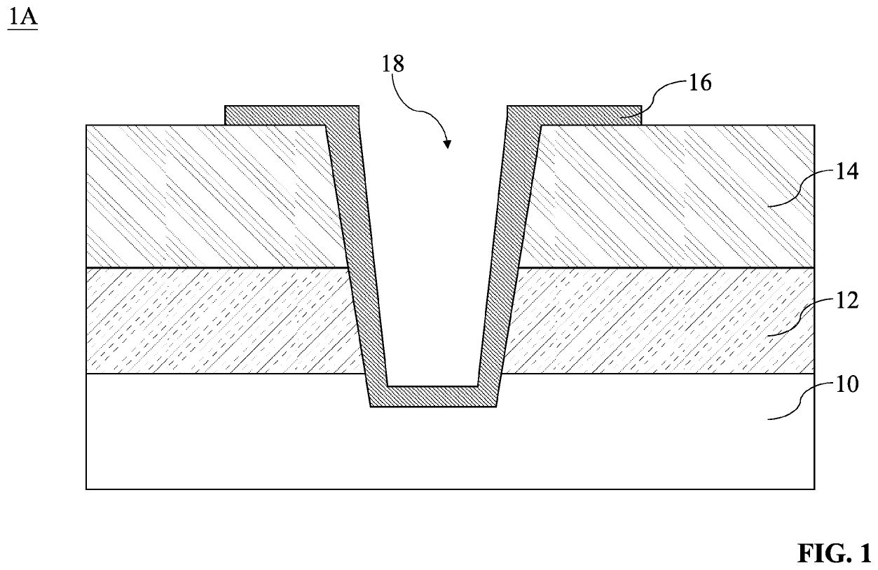

FIG. 1 is a cross sectional view of a nitride-based semiconductor device 1A according to some embodiments of the present disclosure. The nitride-based semiconductor device 1A may include components so it can operate functions, such as I/O device, logic components, transistors. The nitride-based semiconductor device 1A includes a substrate 10, an epitaxy structure 12, an oxide structure 14, and a conductor filling 16.

The substrate 10 may be a semiconductor substrate. The substrate 10 may be a silicon-based substrate. The exemplary materials of the substrate 10 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 10 can include, for example, but is not limited to, group III elements, group IV elements, group V elements, or combinations thereof (e.g., III-V compounds). In other embodiments, the substrate 10 can include, for example but is not limited to, one or more other features, such as a doped region, a buried layer, an epitaxial (epi) layer, or combinations thereof.

The epitaxy structure 12 is disposed over the substrate 10. The epitaxy structure 12 may include a nitride-based buffer layer. The epitaxy structure 12 may include different III-V nitride-based semiconductor layers to form a two-dimensional electron gas (2DEG) region. For example, the epitaxy structure 12 may include a III-V nitride-based semiconductor layer made of exemplary materials of the III-V nitride-based layer 12 that include, for example but are not limited to, nitrides or group III-V compounds, such as GaN, AIN, InN, InxAlyGa(_{1-x-y)}N where x+y≤1, Aly Ga_{(1-y)}N where y≤1. The epitaxy structure 12 may include two III-V nitride-based semiconductor layers having different bandgaps than each other. The two III-V nitride-based semiconductor layers are in contact with each other. The exemplary materials of the two III-V nitride-based semiconductor layers are selected such that one of the two III-V nitride-based semiconductor layers has a bandgap (i.e., forbidden band width) greater/higher than a bandgap of another one of the two III-V nitride-based semiconductor layers, which causes electron affinities thereof different from each other and forms a heterojunction therebetween.

As such, the two III-V nitride-based semiconductor layers can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 1A is available to include at least one GaN-based high-electron-mobility transistor (HEMT).

The oxide structure 14 is disposed over the epitaxy structure 12. The oxide structure 14 can serve as an isolation layer for the epitaxy structure 12. The oxide structure 14 can provide protection for the epitaxy structure 12. The oxide structure 14 may cover the GaN-based HEMT. The exemplary materials of the oxide structure 14 can include, for example but are not limited to, SiNx, SiOx, SiON, SiC, SiBN, SiCBN, oxides, nitrides, or combinations thereof. In some embodiments, the oxide structure 14 is a multi-layered structure, such as a composite dielectric layer of Al₂O₃/SiN, Al₂O₃/SiO₂, AlN/SiN, AlN/SiO₂, or combinations thereof.

In some embodiments, the nitride-based semiconductor device 1A may include electrodes between the epitaxy structure 12 and the oxide structure 14. In some embodiments, the nitride-based semiconductor device 1A may include at least one transistor between the epitaxy structure 12 and the oxide structure 14.

The conductor filling 16 is disposed over the oxide structure 14. The conductor filling 16 can extend from a top surface of the conductor filling 16 to make contact with the substrate 10. The conductor filling 16 can extend along inner sidewalls of the substrate 10, the epitaxy structure 12, and the oxide structure 14. The substrate 10, the epitaxy structure 12, and the oxide structure 14 can collectively have a recess 18 to accommodate the conductor filling 16. The conductor filling 16 formed in the recess 18 can serve as a through-GaN via (TGV) structure. In some embodiments, the conductor filling 16 may include metals or metal compounds. The exemplary materials of the metals or metal compounds can include, for example but are not limited to, W, Cu, Au, Pd, Ti, Ta, Co, Ni, Pt, Mo, TiN, TaN, metal alloys thereof, or other metallic compounds.

The TGV structure is formed after the formation of the oxide structure 14. Prior to the formation of the TGV structure, the formation of the recess 18 needs to run first. The result of the formation of the recess 18 will affect the TGV structure. For example, as a recess having very vertical sidewalls is formed, a TGV structure will tend to peel up from the sidewalls after formation so yield rate reduces. In addition, during formation of a recess for a TGV structure, a target device may be brought to different chambers/reactors so it is hard to avoid process variation almost.

In order to cure such the defect as above, the present disclosure provides a novel manner for forming TGV structures.

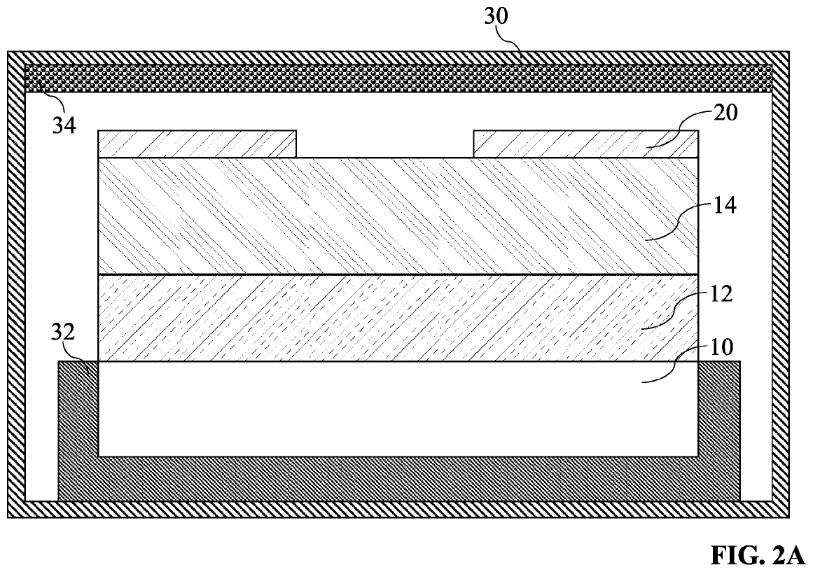

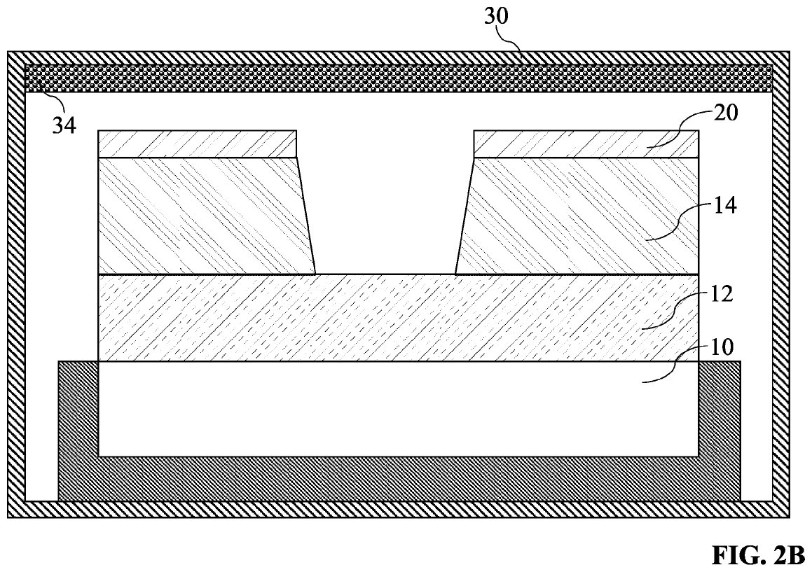

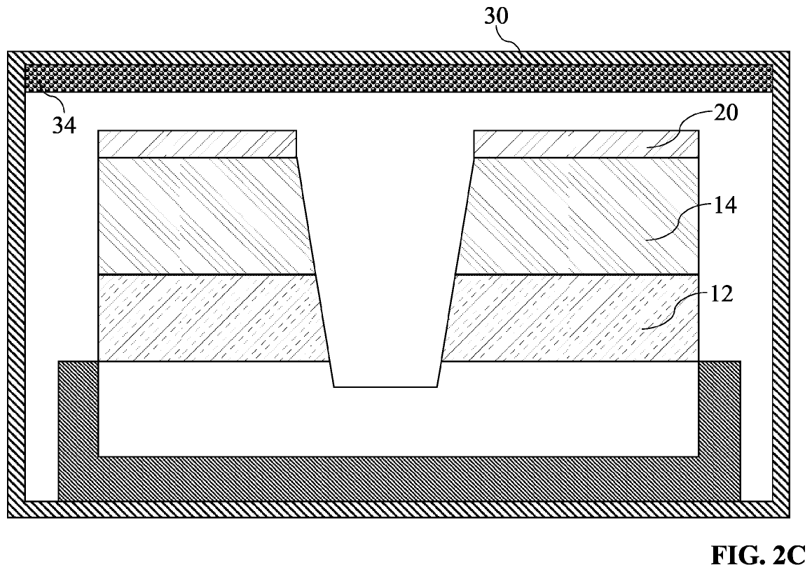

FIG. 2A, FIG. 2B, and FIG. 2C show different stages of a method for manufacturing a nitride-based semiconductor device according to some embodiments of the present disclosure. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a wafer holder 32 holds a substrate 10 in a chamber 30. The chamber 30 may serve as a reactor. An epitaxy structure 12 is formed on the substrate 10. An oxide structure 14 is formed on the epitaxy structure 12. The mask layer 20 is formed on the epitaxy structure 12 and the oxide structure 14. The mask layer 20 has an opening on the oxide structure 14 such that at least one portion of the oxide structure 14 is exposed from the opening in the chamber 30.

In some embodiments, the chamber 30 has an inner surface coated with a chlorine-resistant layer 34. In some embodiments, the coating the chlorine-resistant layer 34 can be performed prior to forming the epitaxy structure 12. In some embodiments, the chlorine-resistant layer 34 is devoid of quartz. In some embodiments, the chamber 30 may have a quartz coating which tends to be damaged by a chlorine-gas, so removing a quartz coating from the chamber 30 can be performed prior to coating the chlorine-resistant layer 34 on the inner surface of the chamber 30.

Referring to FIG. 2B, a first etching process is performed. A first halogen-based gas is introduced into the chamber 30 to remove the exposed portion of the oxide structure 14 such that a portion of the epitaxy structure 12 is exposed. In some embodiments, the first halogen-based gas includes carbon tetrafluoride (CF₄), and the introducing the first halogen-based gas into the chamber 30 can achieve reactive-ion etching (RIE).

Referring to FIG. 2C, a second etching process is performed. A second halogen-based gas is introduced into the chamber 30 to remove the exposed portion of the epitaxy structure 12 such that a portion of the substrate 10 is exposed. In some embodiments, at least one portion of the substrate 10 is removed so that the substrate 10 can have a recess. In some embodiments, the second halogen-based gas includes chlorine (Cl₂), and the introducing the second halogen-based gas into the chamber 30 can achieve reactive-ion etching (RIE).

The first etching process and the second etching process are performed as the structure is in the same chamber 30. Therefore, the recipes of the processes can be easily normalized. That is, the boundary conditions between the first etching process and the second etching process can become more uniform. Controlling process variation is an important issue for two continuous processes. Stability for devices can be improved once the controlling process variation reduced. Because the first etching process and the second etching process are performed as the structure is positioned in the same chamber 30, the performing the second etching process can follow the performing the first etching process without vacuum relief (i.e., no need to let oxygen flow in and then to pump oxygen out with respect to the chamber 30 between the first etching process and the second etching process).

In some embodiments, a pressure at a transition stage between performing the first etching process and performing the second etching process is in a range from 90 mTorr to 110 mTorr. For semiconductor devices, a structure at a transition stage may be damaged due to oxygen, so keeping free from vacuum relief can make process stability improved.

To achieve it, the inner surface of the chamber 30 is coated with the chlorine-resistant layer 34 so the chamber 30 is free from damaged during the reactive-ion etching process which applies chlorine (Cl₂) to the chamber 30.

Under such the condition, the recipes of the second etching process can be tuned. In some embodiments, the introducing the second halogen-based gas into the chamber 30 is performed with a pressure in a range from about 50 mTorr to about 70 mTorr. In some embodiments, the second halogen-based gas is introduced at a gas flow in a range from about 80 sccm to about 100 sccm. The recipes are made so that the second etching process can become smooth.

By this configuration, a removing rate during a removal stage of the exposed portion of the epitaxy structure 12 is in a range from about 130 angstrom per second to about 170 angstrom per second. The removing rate can make inner sidewalls suitable for formation of a conductive layer for TGV structure.

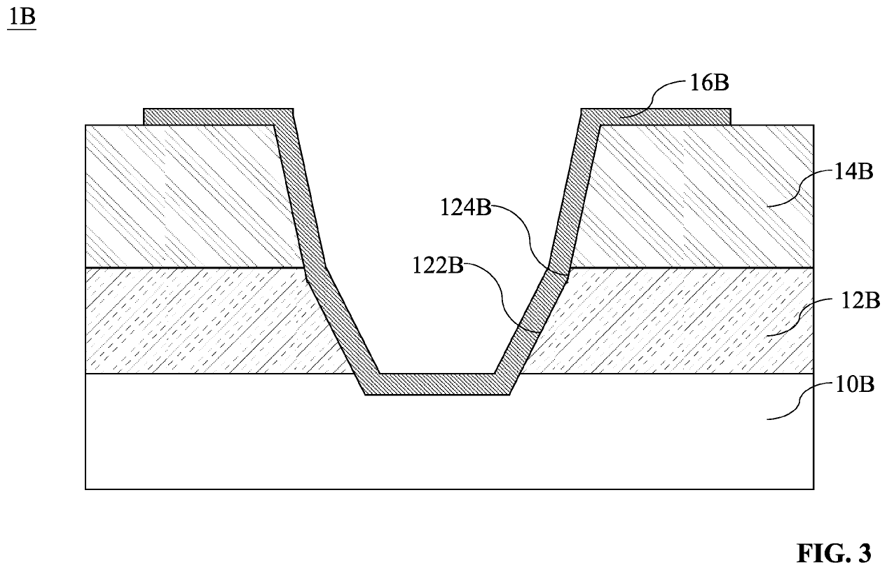

FIG. 3 is a cross sectional view of a nitride-based semiconductor device 1B according to some embodiments of the present disclosure. The nitride-based semiconductor device 1B is similar to the semiconductor device 1A as described and illustrated with reference to FIG. 1, except that an epitaxy structure 12B has two-steps inner sidewalls.

More specifically, the epitaxy structure 12B has an inner sidewall 122B and an inner sidewall 124B. The inner sidewall 122B is connected to a recess of the substrate 10B that is located at a position below the epitaxy structure 12B. The inner sidewall 124B is located at a position above the inner sidewall 122B. The inner sidewall 124B is connected to the inner sidewall 122B. The inner sidewall 124B may be formed in the first etching process and the inner sidewall 122B may be formed in the second etching process, so that the inner sidewall 122B and the inner sidewall 124B may have different characters. For example, the inner sidewall 122B and the inner sidewall 124B have different roughness.

The inner sidewall 122B and the inner sidewall 124B are oblique with respect to substrate 10B. The inner sidewall 122B and the inner sidewall 124B have different angles of inclination with respect to the substrate 10B. With respect to the substrate 10B, the inner sidewall 124B is more oblique than the inner sidewall 122B.

The oxide structure 14B is disposed on the epitaxy structure 12B. The oxide structure 14B has an inner sidewall connected to the inner sidewall 124B of the epitaxy structure 12B and oblique with respect to the substrate 10B. The conductor filling 16B is received by the recess of the substrate 10B. The inner sidewall 124B of the epitaxy structure 12B and the inner sidewall of the oxide structure 14B may have the same obliqueness with respect to the substrate 10B since they are formed in the same etching process.

The conductor filling 16B can extend upward. The conductor filling 16B can extend from a position beneath the epitaxy structure 12B to a position over the oxide structure 14B. The conductor filling 16B attaches to the inner sidewalls 122B and 124B of the epitaxy structure 12B and the inner sidewall of the oxide structure 14B.

The two-steps inner sidewalls 122B and 124B of the epitaxy structure 12B can be taken as evidence that the etching processes for the epitaxy structure 12B and the oxide structure 14B are performed in the same chamber/reactor.

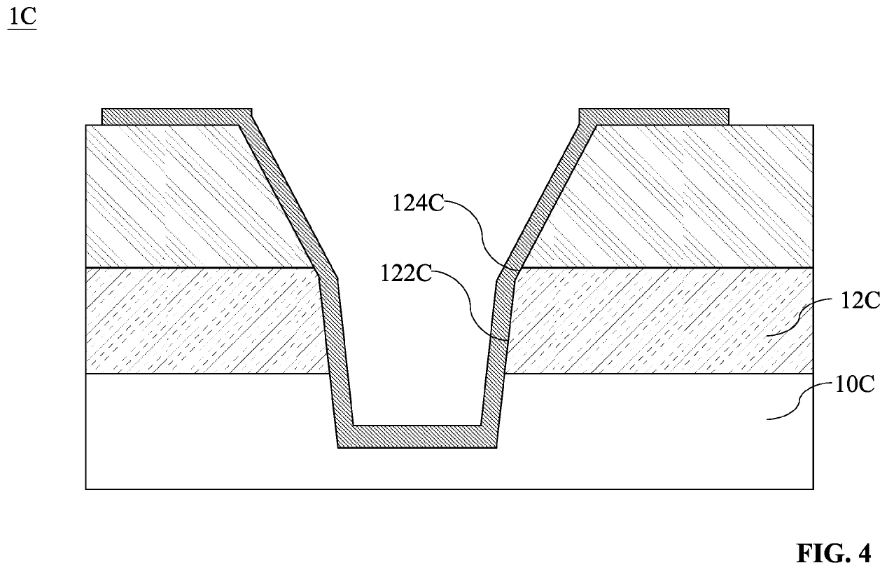

FIG. 4 is a cross sectional view of a nitride-based semiconductor device 1C according to some embodiments of the present disclosure. The nitride-based semiconductor device 1C is similar to the semiconductor device 1A as described and illustrated with reference to FIG. 1, except that an epitaxy structure 12C has two-steps inner sidewalls.

The epitaxy structure 12C has an inner sidewall 122C and an inner sidewall 124C that are oblique with respect to substrate 10C. The inner sidewall 122C and the inner sidewall 124C have different angles of inclination with respect to the substrate 10C. With respect to the substrate 10C, the inner sidewall 122C is more oblique than the inner sidewall 124C.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A method for manufacturing a nitride-based semiconductor device, comprising:
forming an epitaxy structure on a silicon-based substrate;
forming an oxide structure on the epitaxy structure;
forming a mask layer having an opening on the epitaxy structure such that at least one portion of the oxide structure is exposed from the opening in a chamber;
introducing a first halogen-based gas into the chamber to remove the exposed at least one portion of the oxide structure such that a portion of the epitaxy structure is exposed; and
introducing a second halogen-based gas different than the first halogen-based gas into the chamber to remove the exposed portion of the epitaxy structure such that a portion of the silicon-based substrate is exposed.

2. The method of claim 1, wherein the first halogen-based gas comprises carbon tetrafluoride (CF₄), and the second halogen-based gas comprises chlorine (Cl₂), and wherein the oxide structure comprises SiNx, SiOx, SiON, SIC, SiBN, SiCBN, oxides, nitrides, or combinations there of.

3. The method of claim 2, further comprising:
coating a chlorine-resistant layer on an inner surface of the chamber prior to forming the epitaxy structure.

4. The method of claim 3, wherein the chlorine-resistant layer is devoid of quartz.

5. The method of one claim 3, further comprising:
removing a quartz coating from the chamber prior to coating the chlorine-resistant layer on the inner surface of the chamber.

6. The method of claim 1, wherein introducing the second halogen-based gas into the chamber is performed with a pressure in a range from 50 m Torr to 70 m Torr.

7. The method of claim 1, wherein a removing rate during a removal stage of the exposed portion of the epitaxy structure is in a range from 130 angstrom per second to 170 angstrom per second.

8. The method of claim 1, wherein the second halogen-based gas is introduced at a gas flow in a range from 80 sccm to 100 sccm.

9. The method of claim 1, wherein introducing the first halogen-based gas into the chamber is performed to achieve reactive-ion etching, and/or introducing the second halogen-based gas into the chamber is performed to achieve reactive-ion etching.

10. (canceled)

11. A method for manufacturing a nitride-based semiconductor device, comprising:
forming an epitaxy structure on a silicon-based substrate;
forming an oxide structure on the epitaxy structure;
forming a mask layer having an opening on the epitaxy structure such that at least one portion of the oxide structure is exposed from the opening in a chamber;
performing a first reactive-ion etching process in the chamber by using a first halogen-based gas to remove the exposed at least one portion of the oxide structure such that a portion of the epitaxy structure is exposed; and
performing a second reactive-ion etching process in the chamber by using a second halogen-based gas different than the first halogen-based gas to remove the exposed portion of the epitaxy structure such that a portion of the silicon-based substrate is exposed.

12. The method of claim 11, wherein the first halogen-based gas comprises carbon tetrafluoride (CF₄), and the second halogen-based gas comprises chlorine (Cl₂).

13. The method of claim 12, further comprising:
coating a chlorine-resistant layer on an inner surface of the chamber prior to forming the epitaxy structure.

14. (canceled)

15. The method of claim 13, further comprising:
removing a quartz coating from the chamber prior to coating the chlorine-resistant layer on the inner surface of the chamber.

16. The method of claim 11, wherein introducing the second halogen-based gas into the chamber is performed with a pressure in a range from 50 m Torr to 70 m Torr.

17. The method of claim 11, wherein a removing rate during a removal stage of the exposed portion of the epitaxy structure is in a range from 130 angstrom per second to 170 angstrom per second.

18. The method of claim 11, wherein the second halogen-based gas is introduced at a gas flow in a range from 80 sccm to 100 sccm.

19. The method of claim 11, wherein performing the second reactive-ion etching process follows performing the first reactive-ion etching process without vacuum relief.

20. The method of claim 11, wherein a pressure at a transition stage between performing the first reactive-ion etching process and performing the second reactive-ion etching process is in a range from 90 mTorr to 110 mTorr.

21. A nitride-based semiconductor device, comprising:
a silicon-based substrate;
an epitaxy structure disposed on the silicon-based substrate, wherein the epitaxy structure has a first inner sidewall and a second inner sidewall at above the first inner sidewall and connected to the first inner sidewall, and the first inner sidewall and the second inner sidewall have different roughness and are oblique with respect to the silicon-based substrate;
an oxide structure disposed on the epitaxy structure, wherein the oxide structure has an inner sidewall connected to the second inner sidewall and oblique with respect to the silicon-based substrate; and
a conductor filling extending from a position beneath the epitaxy structure to a position over the oxide structure.

22.-2. (canceled).

26. The nitride-based semiconductor device of claim 21, wherein the oxide structure comprises SiNx, SiOx, SiON, SiC, SiBN, SiCBN, oxides, nitrides, or combinations thereof.
